(19) United States
(12) Patent Application Publication
(10) Pub. No.: US 2007/0023745 A1
(43) Pub. Date: Feb. 1, 2007

(54) Strained channel transistor and method of fabricating the same

(75) Inventor: Myung Jin Jung, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/494,348

(22) Filed: Jul. 26, 2006

(30) Foreign Application Priority Data
Jul. 26, 2005 (KR) 10-2005-0067885

(51) Int. Cl. H01L 31/00

(52) U.S. Cl. 257/19

(57) ABSTRACT

A strained channel transistor according to the present invention includes a semiconductor substrate, a semiconductor layer having a lattice constant larger than the lattice constant of the semiconductor substrate on the semiconductor substrate, a strained channel layer on the semiconductor layer, and one or more epitaxial layers on sides of the strained channel layer, configured to change the lattice structure of the strained channel layer. Trenches may be formed in the strained channel layer, and the epitaxial layer(s) formed in the trenches, and stress from the epitaxial layer may increase the strained channel layer's lattice distance, and in the end, enhance the mobility of charge carriers through the channel.

This application claims the benefit of Korean Application No. 10-2005-0067885, filed on Jul. 26, 2005, which is incorporated by reference herein in its entirety.

### BACKGROUND OF THE INVENTION

1. Field of the Invention

The present invention relates to a semiconductor device and a fabrication method thereof, and more particularly, to a strained channel transistor and a method of fabricating the same, in which the mobility of electro-charges is enhanced.

2. Description of the Related Art

To meet the trend toward a low power consumption and a high operational speed of a transistor, a strained channel transistor has been developed, of which a channel is formed to have a large lattice parameter, thereby enhancing the mobility of electro-charges through the channel.

In general, a germanium layer having the second lattice constant (e.g., a relatively large interatomic distance) is formed on the silicon substrate having the first lattice constant (e.g., a relatively small interatomic distance), and a silicon layer is additionally formed on the germanium layer, so that the silicon layer having a lattice constant larger than the first lattice constant can be formed on the top of the silicon substrate. Thus, the silicon layer can be formed as a strained channel layer of the transistor having the lattice constant larger than that of the silicon substrate.

FIG. 1 is a cross-sectional view of a conventional strained channel transistor. Referring to FIG. 1, a conventional transistor having a strained channel comprise a germanium layer 12 formed on a silicon substrate 10 having the first lattice constant, and a silicon layer 14 formed on the germanium layer 12. Here, the germanium layer 12 has the second lattice constant larger than the first lattice constant of the silicon substrate 10.

Because the silicon layer 14 is epitaxially grown on the germanium layer 12 having the lattice constant larger than the lattice constant of a typical silicon material, the lattice constant of the silicon layer 14 is getting larger, thus forming a strained layer. An isolation layer 16 formed on the substrate comprising the silicon substrate 10, the germanium layer 12, and the strained silicon layer 14, defines an active area. In addition, a gate pattern 18, a source region 20s, and a drain region 20d are formed in the silicon layer 14 of the active area. Since a channel of the transistor is formed in the strained silicon layer 14, as the top layer of the silicon substrate, the mobility of electro-charge through the channel is higher than the mobility of electro-charge through an ordinary silicon layer.

However, as a channel length of a transistor is decreased, there are disadvantages that the mobility of electro-charges or charge carriers (particularly, holes) through the channel may deteriorate in a PMOS (P-channel Metal Oxide Semiconductor) transistor, which transfers signals by the movement of the hole through the channel, even though the channel is formed in the strained silicon layer.

### SUMMARY OF THE INVENTION

It is, therefore, an object of the present invention to provide a strained channel transistor, in which the mobility of electro-charges or charge carriers through the channel can be enhanced, and a method of fabricating the same.

To achieve the above objects, a strained channel transistor according to the present invention comprises: a semiconductor substrate; a semiconductor layer having a larger lattice constant than a lattice constant of the semiconductor substrate on the semiconductor substrate; a strained channel layer on the semiconductor layer; one or more epitaxial layers on sides of the strained channel layer configured to change a lattice structure or lattice constant of the strained channel layer; a gate on the strained channel layer; and source and drain regions on or in the epitaxial layer.

A strained channel transistor according to the present invention may comprise a germanium layer on a silicon substrate, and a strained channel in the silicon layer on the germanium layer. As the epitaxial layer is adjacent to (and usually in contact with) the strained channel layer, the channel layer's lattice distance increases as a result of stress from the epitaxial layer, and in the end, enhancing the mobility of electro-charges or charge carriers through the channel.

A manufacturing method of a strained channel transistor according to the present invention comprises the steps of forming a semiconductor layer having a lattice constant larger than a lattice constant of a semiconductor substrate; forming a strained semiconductor layer on the semiconductor layer; and forming an epitaxial layer in a trench region formed by etching the strained semiconductor layer.

The trench region defines a channel region, and the lattice distance of the strained semiconductor layer is broader by stress of the epitaxial layer formed in the trench region. A gate can be formed on the channel region, and source/drain regions can be formed in the epitaxial layer.

According to the present invention, a transistor channel in the strained semiconductor layer may make a heterojunction with the epitaxial layer, and as a result, a strained channel having a lattice distance increased even more by a stress applied from the epitaxial layer can be formed. Because the lattice distance of the strained channel according to the present invention may be increased even more than a conventional strained semiconductor layer, the mobility of electrical charge carriers through the channel can be enhanced, and the operational speed of PMOS (P-channel Metal Oxide Semiconductor) transistors (which transfer a signal using holes having a relatively low mobility) can be enhanced. And, a semiconductor device that consumes low power and operates at high speed can be fabricated by applying the strained channel according to the present invention, particularly to semiconductor devices having a transistor channel width below 65 nm.

### BRIEF DESCRIPTION OF DRAWINGS

FIG. 1 is a cross-sectional view of a conventional strained channel transistor.

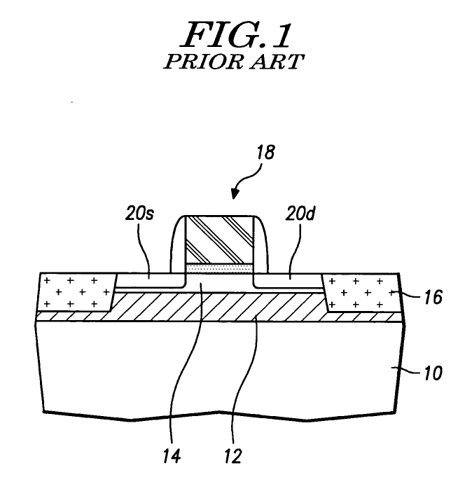

FIG. 2 is a cross-sectional view of an embodiment of a strained channel transistor according to the present invention.

FIGS. 3 to 5 are cross-sectional views illustrating a method for fabricating a strained channel transistor according to an embodiment of the present invention.

### DETAILED DESCRIPTION OF THE INVENTION

Hereinafter, a preferred embodiment of the present invention will be described in detail with reference to the accompanying drawings.

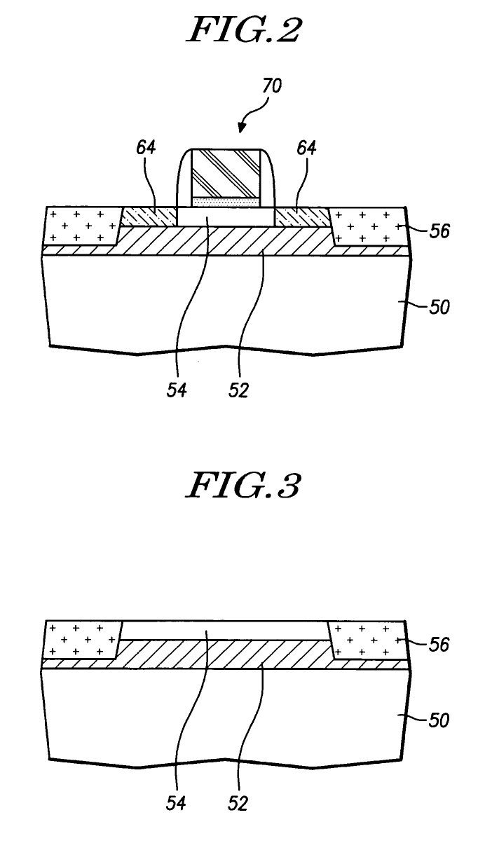

FIG. 2 is a cross-sectional view of an embodiment of a strained channel transistor according to the present invention. As shown in FIG. 2, the strained channel transistor comprises a semiconductor layer 52 formed on the semiconductor substrate 50, a strained channel layer 54 formed on the semiconductor layer 52, and an epitaxial layer 64 formed on both sides of the strained channel layer 54. A gate pattern 70 is formed on the strained channel layer 54, and source/drain regions are formed on the epitaxial layer 64.

The semiconductor substrate 50 comprises a material having a first lattice constant, e.g., a crystalline silicon substrate having a first interatomic distance in the crystal lattice, and the semiconductor layer 52 can be formed of a germanium layer having a second lattice constant (e.g., interatomic distance) larger than the lattice constant of silicon. The strained channel layer 54 can be formed from a silicon layer in which the distance between atoms in the lattice is increased, for example by making silicon's density increased gradually on the semiconductor layer 52.

According to an embodiment of the present invention, the strained channel layer 54 and the epitaxial layer 64 form an active region defined by an isolation layer 56. Further, the gate (e.g., comprising gate pattern 79) is formed across a top portion of the active region. Namely, the strained channel layer 54 can be formed under the gate pattern. Here, since the epitaxial layer 64 comprises a material in contact with the strained channel layer 54, thus applying stress to the strained channel layer 54, the strained channel layer 54 can be further deformed. Therefore, the distance between atoms in the lattice of the strained channel layer 54 can become larger when in contact with the epitaxial layer 64 having a relatively large lattice parameter. Consequently, the strained channel layer 54 of which the lattice distance become larger can improve the mobility of electric charges such as holes.

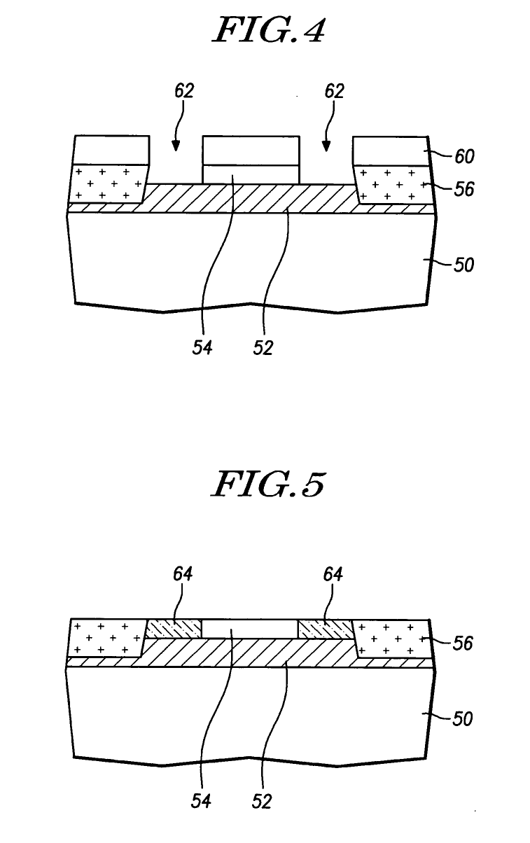

FIGS. 3 to 5 are cross-sectional views illustrating a method for fabricating a strained channel transistor according to an embodiment of the present invention.

As shown in FIG. 3, a semiconductor layer 52 having a second lattice constant is formed on the semiconductor substrate 50 that has the first lattice constant. The second lattice constant (e.g., distance between atoms, or interatomic distance) is larger than the first lattice constant. For example, if the semiconductor substrate 50 comprises a silicon substrate (such as a crystalline silicon wafer, or other substrate having a polycrystalline or crystalline [e.g., epitaxial] silicon layer on the surface), the semiconductor layer 52 can comprise or consist essentially of a material which has a lattice constant larger than that of silicon, selected from the group consisting of germanium, silicon-germanium (SiGe), silicon carbide, InP, CdSe, ZnTe and MgSe, etc. Preferably, the semiconductor layer 52 comprises germanium (e.g., Ge or SiGe) or consists essentially of germanium, according to an embodiment of the present invention.

Next, the strained semiconductor layer 54 is formed by epitaxially growing a semiconductor material, such as a silicon material (which typically has the first lattice constant), in a bulk state on the semiconductor layer 52. Particularly, because a germanium layer has generally a lattice parameter (e.g., interatomic distance) larger than a typical silicon material, the lattice distance of silicon in the strained semiconductor layer 54 grown on the semiconductor layer 52 including germanium can be enlarged, thus resulting in the strained semiconductor layer 54 with the lattice constant larger than that of conventional bulk silicon.

As shown in FIG. 3, after forming the strained semiconductor layer 54 on the semiconductor layers 52, the active region is defined by forming a plurality of isolation structures (comprising one or more dielectric and/or insulator layers) 56 on the substrate comprising the strained semiconductor layer 54.

As shown in FIG. 4, after forming the isolation layer 56, a mask layer 60 is formed on the semiconductor substrate. The mask layer 60 covers the region where the channel of the transistor will be formed, and has an opening through which the active region is exposed. Using the mask layer 60 as an etch mask, the exposed portion of the strained semiconductor layer 54 by the opening is etched to form a trench region 62. In this etching process, the exposed portion of the strained semiconductor layer 54 can be completely removed to expose the semiconductor layer 52, a portion of the strained semiconductor layer 54 can remain on the semiconductor layer 52. Although mask 60 is shown in alignment with isolation layer/structures 56, such alignment is not necessary. For example, an etch chemistry that selectively etches strained semiconductor layer 54 relative to isolation layer/structures 56 (in addition to semiconductor layer 52) may be selected. Alternatively, a portion of strained semiconductor layer 54 can remain adjacent to an isolation layer/structure 56 without substantial adverse effects.

After forming the trench region 62, an epitaxial layer 64 is grown in the trench region 62 using the mask layer 60 as a growth-blocking layer. As shown in FIG. 5, because the strained layer 54 is stressed by growth of the epitaxial layer 64, the lattice structure (and particularly interatomic distances) in part or all of the strained semiconductor layer 54 may be deformed by a heterojunction with the epitaxial layer 64, particularly a portion of strained semiconductor layer 54 in contact with the epitaxial layer 64. Therefore, when the strained semiconductor layer 54 contacts the epitaxial layer 64 having a larger lattice constant, the lattice distance of the strained semiconductor layer 54 can become more enlarged.

Thus, the epitaxial layer 64 is preferably comprises or consists essentially of a material having a larger lattice constant (e.g., interatomic distance) than the strained semiconductor layer 54. For example, when the strained semiconductor layer 54 comprises or consists essentially of silicon, the epitaxial layer 64 can include one or more members of the group consisting of germanium, silicon-germanium (SiGe), silicon carbide, InP, CdSe, ZnTe and MgSe, which have at least one lattice constant larger than silicon. According to an embodiment of the present invention, it is preferable that the epitaxial layer 64 comprises or consists essentially of germanium. It is contemplated that the epitaxial layer 64 can comprise a plurality of epitaxial layers, the first of which has a larger lattice constant (e.g., interatomic distance) than the strained semiconductor layer 54, where subsequent layer(s) may comprise the same or different semiconductor material (e.g., Ge, SiGe, or Si).

Subsequently, according to typical processes for manufacturing a transistor, a gate comprising gate pattern 70 is formed on the strained semiconductor layer 54, as shown in FIG. 2. In addition, source/drain regions can be formed in the epitaxial layer 64 on sides of the gate pattern 70, as shown in FIG. 5.

While the invention has been particularly shown and described with reference to the preferred embodiments thereof, it will be understood by those skilled in the art that various changes in form and detail may be made therein without departing from the sprit and scope of the invention as defined by the appended claims.

What is claimed is:

1. A strained channel transistor, comprising:
a semiconductor substrate comprising a first material having a first lattice constant;
a semiconductor layer on the semiconductor substrate, the semiconductor layer comprising a second material having a second lattice constant larger than the first lattice constant;
a strained channel layer on the semiconductor layer;
one or more epitaxial layers on sides of the strained channel layer configured to change the lattice structure of the strained channel layer;
a gate on the strained channel layer; and
source and drain regions on or in the epitaxial layer.

2. The strained channel transistor of claim 1, wherein the strained channel layer has a third material having a third lattice constant, where the second lattice constant is larger than the third lattice constant.

3. The strained channel transistor of claim 1, wherein the semiconductor substrate comprises silicon, and the semiconductor layer comprises a member selected from the group consisting of germanium, silicon-germanium (SiGe), silicon carbide, InP, CdSe, ZnTe and MgSe.

4. The strained channel transistor of claim 3, wherein the semiconductor substrate comprises crystalline or polycrystalline silicon, and the semiconductor layer comprises germanium or silicon-germanium (SiGe).

5. The strained channel transistor of claim 2, wherein the semiconductor substrate comprises silicon, and the semiconductor layer comprises a member selected from the group consisting of germanium, silicon-germanium (SiGe), silicon carbide, InP, CdSe, ZnTe and MgSe.

6. The strained channel transistor of claim 5, wherein the semiconductor substrate comprises crystalline or polycrystalline silicon, and the semiconductor layer comprises germanium or silicon-germanium (SiGe).

7. The strained channel transistor of claim 1, wherein strained channel layer comprises silicon, and the epitaxial layer comprises a member selected from the group consisting of germanium, silicon-germanium (SiGe), silicon carbide, InP, CdSe, ZnTe and MgSe.

8. The strained channel transistor of claim 2, wherein strained channel layer comprises silicon, and the epitaxial layer comprises a member selected from the group consisting of germanium, silicon-germanium (SiGe), silicon carbide, InP, CdSe, ZnTe and MgSe.

9. The strained channel transistor of claim 1 or 2, wherein the semiconductor substrate comprises crystalline or polycrystalline silicon, the strained channel layer comprises silicon, and the epitaxial layer effectively deforms the lattice distance of the strained channel layer.

10. A method for manufacturing a strained channel transistor, comprising the steps of:
forming a semiconductor layer on a semiconductor substrate, the semiconductor substrate comprising a first material having a first lattice constant and the semiconductor layer comprising a second material having a second lattice constant larger than the first lattice constant;
forming a strained semiconductor layer on the semiconductor layer;
forming a plurality of trenches by patterning the strained semiconductor layer, the plurality of trenches defining a channel region;
growing an epitaxial layer in the trenches, the epitaxial layer contacting the channel region;
forming a gate on the channel region; and
forming source and drain regions in the epitaxial layer.

11. The method of claim 10, wherein forming the plurality of trenches comprises the steps of:
forming a mask layer to cover the channel region on the strained semiconductor layer; and
etching the strained semiconductor layer to form the plurality of trenches.

12. The method of claim 11, wherein the epitaxial layer is grown using the mask layer as a growth blocking layer.

13. The method of claim 10, wherein the strained semiconductor layer comprises silicon.

14. The method of claim 13, wherein the epitaxial layer comprises a member selected from the group consisting of germanium, silicon-germanium (SiGe), silicon carbide, InP, CdSe, ZnTe, and MgSe.

15. The method of claim 14, wherein the epitaxial layer comprises germanium or silicon-germanium (SiGe).

16. The method of claim 11, wherein the strained semiconductor layer comprises silicon.

17. The method of claim 16, wherein the epitaxial layer comprises a member selected from the group consisting of germanium, silicon-germanium (SiGe), silicon carbide, InP, CdSe, ZnTe, and MgSe.

18. The method of claim 17, wherein the epitaxial layer comprises germanium or silicon-germanium (SiGe).
